(19) United States
(12) Patent Application Publication
(10) Pub. No.: US 2011/0300718 A1
(43) Pub. Date: Dec. 8, 2011

(54) ON-WAFER CRYSTALLIZATION FOR PURE-SILICA-ZEOLITE ULTRA LOW-K FILMS

(75) Inventors: Yushan YAN, Riverside, CA (US); Junlan Wang, Bellevue, WA (US); Yan Liu, Riverside, CA (US); Rui Cai, Dalian (CN)

(73) Assignee: The Regents of the University of California, Oakland, CA (US)

(21) Appl. No.: 12/977,437

(22) Filed: Dec. 23, 2010

Related U.S. Application Data
(63) Continuation of application No. 12/775,908, filed on May 7, 2010, now abandoned.
(60) Provisional application No. 61/176,827, filed on May 8, 2009.

(51) Int. Cl. H01L 21/31; C01B 39/00

(52) U.S. Cl. 438/782; 423/711; 423/701; 423/702; 423/704; 257/E21.24

(57) ABSTRACT

An on-wafer crystallization method of spin-coating a silicon wafer with a low-k dielectric zeolite material which includes the steps of forming a synthesis solution; generating a nucleated precursor solution; spin-coating the nucleated precursor onto a substrate as a precursor film; and annealing the precursor film into a zeolite film.

### CROSS-REFERENCE TO RELATED APPLICATION

This patent application is a continuation of U.S. patent application Ser. No. 12/775,908, filed May 7, 2010, which claims priority to U.S. Provisional Patent Application Ser. No. 61/176,827, filed May 8, 2009, and which are incorporated herein by reference in their entirety.

### GOVERNMENT INTEREST

The U.S. Government has a paid-up license in this invention and the right in limited circumstances to require the patent owner to license others on reasonable terms as provided for by the terms of Grant No. CTS-0404376 awarded by National Science Foundation.

### BACKGROUND

The continuous downscaling of microprocessors demands the timely development of ultra-low-dielectric-constant (k) materials to reduce parasitic capacitance, enable faster switching speeds and lower power dissipation. The stringent requirements for the ultra-low-k films by 2012 include not only a low k-value of 1.8 to 2.1, but also other necessary characteristics, such as high thermal conductivity, strong mechanical strength, low surface roughness, high degree of hydrophobicity, and uniform pore size distribution. While the semiconductor industry has developed suitable alternative films with the k-value between 2.5 and 2.9, it would be desirable to have a solution to the k-value below 2.1.

### SUMMARY

In accordance with an exemplary embodiment, an on-wafer crystallization method of spin-coating a silicon wafer with a low-k dielectric zeolite material comprises: forming a synthesis solution; generating a nucleated precursor solution; spin-coating the nucleated precursor onto a substrate as a precursor film; and annealing the precursor film into a zeolite film.

In accordance with an exemplary embodiment, an on-wafer crystallization method of spin-coating a silicon wafer with a low-k dielectric zeolite material comprises: generating a nucleated precursor solution from a synthesis solution; spin-coating the nucleated precursor solution onto a substrate as a precursor film; and annealing the precursor film into a zeolite film.

In accordance with another exemplary embodiment, a method of forming a nucleated precursor solution for on-wafer crystallization for pure-silica-zeolite films comprises: preparing a synthesis solution; heating the synthesis solution to a temperature of approximately 50° C. to 120° C. for approximately 1 to 5 days and then to a temperature of approximately 80° C. to 150° C. for approximately 1 to 5 days to form a suspension of nuclei and crystals; and separating the nuclei from the crystals by centrifugation.

In accordance with a further exemplary embodiment, a method of forming a nucleated solution for on-wafer crystallization for pure-silica-zeolite films comprises: preparing a synthesis solution; and heating the synthesis solution to a temperature of approximately 80° C. for approximately 10 days to 15 days to form a nucleated solution.

In accordance with another exemplary embodiment, a method of forming a nucleated solution for on-wafer crystallization for pure-silica-zeolite films comprises: preparing a synthesis solution; and heating the synthesis solution to a temperature of approximately 50° C. to 120° C. for approximately 5 days to 30 days to form a nucleated solution. In accordance with another exemplary embodiment, two nucleated solutions are mixed with different nucleation times to form a final nucleated solution for spin-on use.

It is to be understood that both the foregoing general description and the following detailed description are exemplary and explanatory and are intended to provide further explanation of the invention as claimed.

### BRIEF DESCRIPTION OF THE DRAWINGS

For a better understanding of the nature of the features of the invention, reference should be made to the following detailed description taken in conjunction with the accompanying drawings, in which:

FIGS. 1(a)-1(c) are HRTEM (High-Resolution Transmission Electron Microscopy) images of (a) H-MEL film demonstrating long-range lattice of MEL crystal; (b) H-MEL film lattices of approximately 10 nm coming from crystallization of leftover precursor; and (c) Lattice in leftover precursor film after annealing;

FIG. 2 are HR-TEM images of a precursor film (FIG. 2(a)) and a SZS (semi-zeolitic silica) film (FIG. 2(b)-(c)), respectively, wherein before annealing no lattice is observed

(FIG. 2(a)), and after annealing, regular lattices are demonstrated (circled in FIG. 2(b), and a zoom-in image (FIG. 2(c)));

FIG. 3 are XRD (X-ray Diffraction) patterns showing the growth from amorphous precursors into MEL structure during annealing;

FIG. 4 are FT-IR (Fourier transform spectroscopy) spectra of different silicas, indicating the zeolitic-structure formation from precursors during annealing by the ratio of band A over band B;

FIG. 5 are normalized TGA (thermogravimetric analysis) curves of (a) MEL nanocrystals, (b) MEL nanoparticles, (c) SZS (semi-zeolitic silica), and (d) N-ZS (non-zeolitic-silica);

FIG. 6 is a chart showing adsorption/desorption isotherms of tolune in the PSZ (pure-silica zeolite) MEL film and SZS (semi-zeolitic silica) film carried out by the ellipsometric porosometry, and wherein the adsorption and desorption isotherms for the SZS film are the same;

FIG. 7 is a meso-pore size distribution in the A-MEL and H-MEL films calculated from toluene adsorption and desorption isotherms obtained by the ellipsometric porosometry, and wherein schematics of particles packing are shown in the inset;

FIG. 8 are optical microscopy images of (a) striated H-MEL films and (b) striation-free A-MEL films, and AFM (atomic force microscopy) images of (c) H-MEL films and (d) A-MEL films;

FIG. 9 are SEM images of a semi-zeolitic silica (SZS) film, including (a) a top view, and (b) a cross-sectional view; and

FIG. 10 is a diagram of an on-wafer crystallization process in accordance with an exemplary embodiment.

FIG. 11 shows ratio of Band A over Band B in FT-IR spectra of different silicas (Table 1).

FIG. 12 shows assignment and weight loss of TGA curves for different types of silicas (Table 2).

FIG. 13 is a comparison between A-MEL film and H-MEL dielectric films (Table 3).

### DETAILED DESCRIPTION

Reference will now be made in detail to the present preferred embodiments of the invention, examples of which are illustrated in the accompanying drawings and tables.

Zeolites are crystalline aluminosilicates with uniformly nanoporous structure which have been commercially used as catalysts, adsorbents, and ion exchangers. Zeolite films are of interest nowadays due to the applications encompassing selective membrane, chemical sensors, low-k dielectric films, antibiotic surface coating, hydrophilic coating, heat pump, thermoelectrics, and corrosion resistant coatings. Traditionally, zeolite films were prepared by in-situ growth, seeded growth or spin-coating. The former two methods require the immersion of the substrate inside the mother liquid and go through high temperature and autogenous pressure within an autoclave. The latter method also demands the hydrothermal synthesis of the zeolite suspension before spin-coating.

In accordance with an exemplary embodiment, a semi-zeolitic silica (SZS) has been developed whose precursor demonstrates amorphous features, and which crystallize via annealing at ambient pressure and thereafter possess zeolite-like structure. It can be appreciated that the convenience to crystallize offers a variety of routes to engineer SZS or SZS films with tunable crystallinity as well as other adjustable properties, which can take the place of the traditional applications of zeolite crystals. In addition, in accordance with another exemplary embodiment, the synthesis of a SZS precursor does not involve high-pressure hydrothermal synthesis, such that the process is industry friendly.

It can be appreciated that pure-silica-zeolite (PSZ) MFI and MEL films have proven to be promising ultra-low-k candidates due to their crystallinity. Two film deposition techniques have been developed: in-situ crystallization and spin-on of hydrothermally synthesized zeolite nanoparticle suspension. Within them, the spin-on process is advantageous for its commercial viability. However, it can be appreciated that one challenge for the spin-on process is that it requires a zeolite nanoparticle suspension with both small particle size and high zeolite yield simultaneously because large particle size can lead to a rough surface and striations. The low zeolite yield from the spin-on process also presently does not generate spin-coated films with enough mechanical strength, hydrophobicity, and low-k-value as desired for certain applications. In order to achieve a desirable zeolite yield (i.e., >60%), the conventional hydrothermal synthesis method produces crystals in micron size, which are too large for spin-coating.

In accordance with an exemplary embodiment, a two-stage synthesis technique has been developed, which achieves and produces small zeolite particles with high yield by decoupling nucleation and crystal growth. For example, in accordance with an exemplary embodiment, a synthesis solution (e.g., tetraethyl orthosilicate (TEOS, 98%, Aldrich), tetrabutylammonium hydroxide (TBAOH, 40%, Sachem), and double deionized water) is first heated at approximately 50° C. to 120° C., and most preferably approximately 80° C. for 1 to 5 days for nucleation without crystal growth. The temperature is then increased to approximately 80° C. to 150° C., and most preferably approximately 114° C. and kept there for 1 to 5 days (i.e., several hours) to grow the nuclei into small crystals. This two-stage hydrothermal synthesis method produces PSZ MEL (pure-silica-zeolite MEL) particles of around 80 nm diameter with the crystal yield of approximately 60%. In addition, in accordance with another exemplary embodiment, an evaporation-assisted two-stage synthesis method includes an evaporation process, which is added between nucleation and crystal growth to increase secondary nucleation. It can be appreciated that the synthesized nanoparticle suspensions as described herein have shown bi-modal particle size distribution at 60 nm and 14 nm at the crystal yield of 60%. In addition, the spin-coated films with these two types of suspensions possess k-values as low as 1.9 with acceptable mechanical strength.

It can be appreciated that the above-mentioned process is not limited to zeolite-type MEL, and that the process can be applied to other types of zeolites. For example, in accordance with an exemplary embodiment, the synthesis solution can include a silica source, such as a silica source, such as tetraethylorthosilicate, ludox, and/or fumed silica, an organic structure directing agent, such as a quaternary ammonium compound, and a solvent, such as water or ethanol.

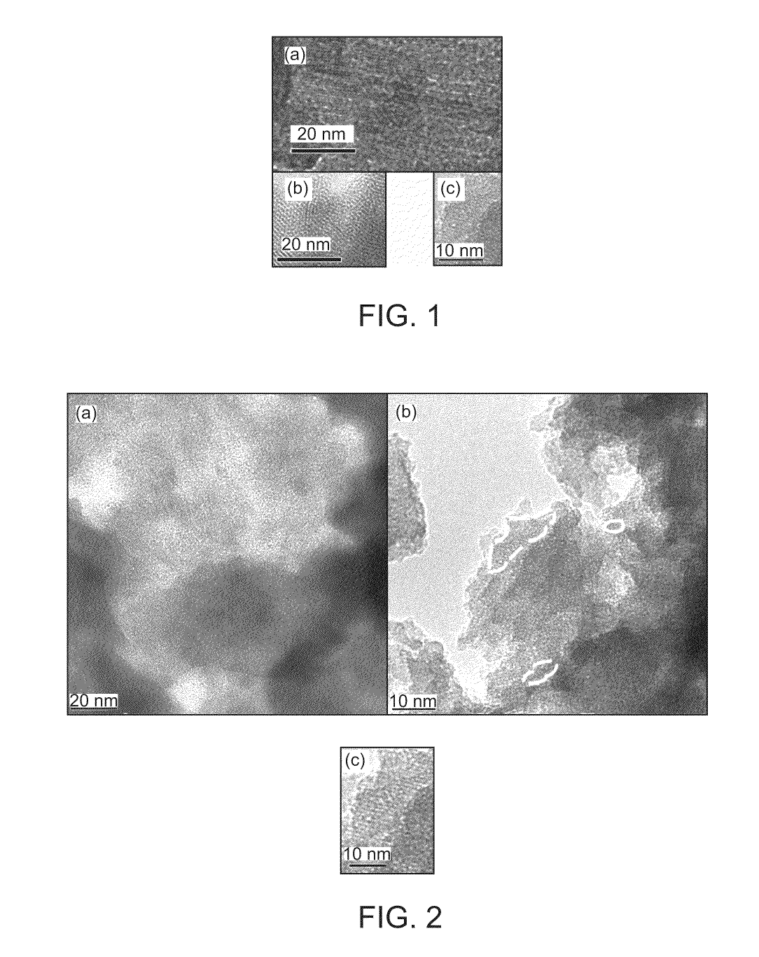

In accordance with an exemplary embodiment, a simple film deposition method is described herein that produces a zeolite thin film on a silicon wafer, and which bypasses and avoids the undesirable crystal size and yield of other known methods. It can be appreciated that in the aforementioned PSZ MEL nanoparticle suspension by two-stage synthesis, apart from the 60% of the silica being crystal, high resolution transmission electron microscopy (HRTEM, FIG. 1) images of the two-stage prepared MEL films, not only demonstrate long-range lattices representing the MEL crystals (FIG. 1(a)), but also lattices in short scale around 10 nm (FIG. 1(b)), which likely come from the crystallization of the rest (i.e., 40%) of the silica. In accordance with an exemplary embodiment, the crystals were centrifuged out to verify this hypothesis. The leftover solution was examined by dynamic light scattering (DLS) and no particles were detected. In addition, the HRTEM images of the spin-coated films from the leftover solution exhibit no lattices before annealing. However, after post-spin (on-wafer) annealing, the leftover film shows lattices (FIG. 1(c)) similar to the short-range ones in the MEL films. It can be appreciated that the leftover solution possesses nuclei precursors, which can undergo on-wafer crystallization to grow into crystalline structures and thus exhibit low-k value and strong mechanical strength.

In accordance with an exemplary embodiment, to take advantage of this nucleated precursor and avoid the waste of 60% of the silica (that took a long time to synthesize and then spun away as nanocrystals), the synthesis solution was aged at 50° C. to 120° C. in a plastic bottle (similar to the first-stage of the two-stage synthesis) to generate a reservoir of nuclei. The nucleated precursor was then spun-onto a silicon wafer and the spun-on film was annealed to grow the nuclei precursor into zeolite films which can be applied as low-k dielectrics. It can be appreciated that in accordance with an exemplary embodiment, this annealing process can be termed as “on-wafer crystallization”. Moreover, the spin-on of the nucleated solution bypasses the aforementioned particle size and yield concerns for low-k application of spin-coating with nanocrystal suspensions.

As set forth herein, the films spin coated with hydrothermally synthesized MEL nanoparticle suspension are referred as “H-MEL”. The films spin-coated with the leftover precursor after annealing is referred as “L-MEL”, and the leftover solution is referred as “L-precursor”. The films spin-coated with the precursor aged directly is referred as “A-MEL” after annealing and the corresponding precursor before annealing is called “A-precursor”.

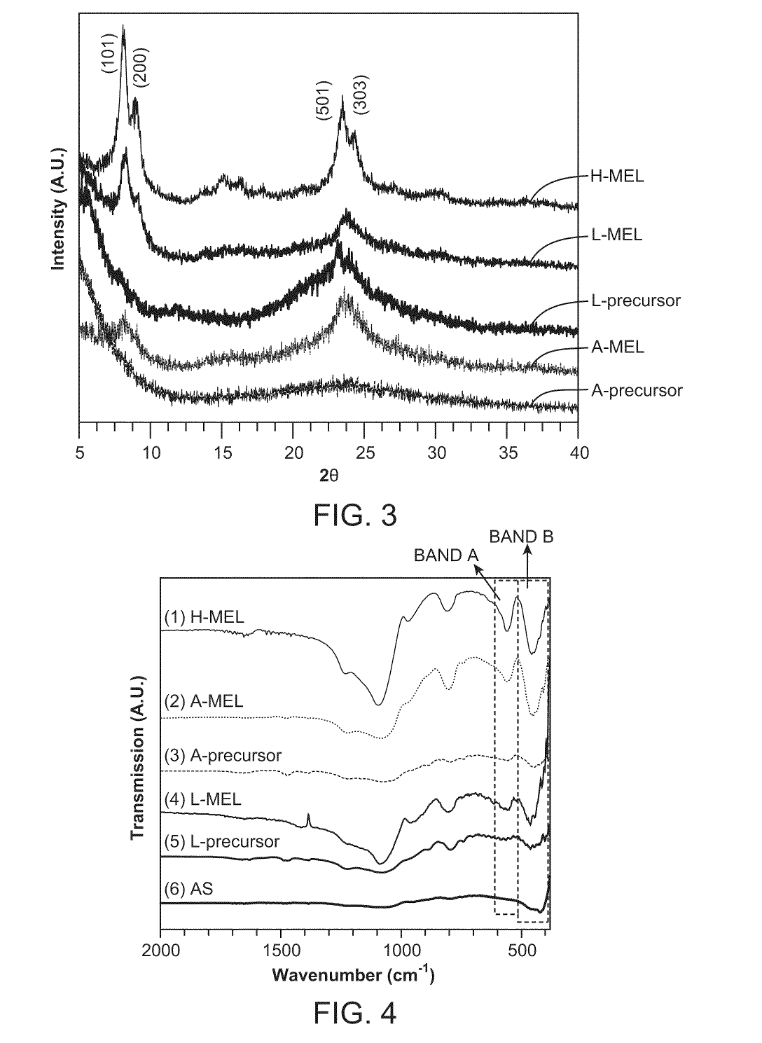

In addition, the XRD patterns of both L-MEL and A-MEL show the characteristic peaks of MEL (relatively broad due to small size) whereas the corresponding precursors only show that of the amorphous structure. In the FT-IR spectra of different types of silicas, all the silicate bands (1100-1020 (vs.), 800-700 (mw), and 480-440 cm⁻¹ (s)) tend to be stronger after annealing due to better cross-linking. According to the Flanigen-Khatami-Szymanski correlation, the band B (480-440 cm⁻¹) is supposed to appear in all the silicas or quartz, including amorphous silica, whereas the band A (650-550 cm⁻¹) has been empirically assigned to a pentasil framework (which includes a zeolite MEL framework). Therefore the ratio of band A over B offers a good indicator of the similarity to MEL structure. The area ratios of the Gaussian fitting of the two bands are listed in Table 1. For comparison, a pure amorphous non-zeolitic-silica (“N-ZS”) (i.e., amorphous silica (“AS”)) was synthesized whose chemical content was similar to the precursor except for the difference in the ratio of silica to structure directing agent. As shown in Table 1, both L-precursor and A-precursor have much higher ratios than the N-ZS (or AS) and the ratios increase after annealing. As shown in FIGS. 3 and 4, the XRD and FT-IR results indicate that both precursors possess nuclei which can undergo on-wafer crystallization during annealing to grow into MEL structures and possess the desired features for low-k applications.

In accordance with an exemplary embodiment, the on-wafer crystallization provides a new route to prepare zeolite films (not necessarily restricted to MEL), which essentially avoids the trade-off between crystal yield and particle size as for the H-MEL films. In addition, the on-wafer crystallization also eliminates a hydrothermal step from the two-stage synthesis route. Therefore, the A-MEL films can be prepared completely at ambient pressure, which is more convenient to industry.

In accordance with another exemplary embodiment, methods of developing SZS precursor have been developed including a leftover after centrifugation of the as-synthesized PSZ MEL suspension (L-precursor) and an aged at ambient pressure precursor (A-precursor). It can be appreciated that the step of centrifugation of the as-synthesized PSZ MEL suspension (L-precursor) or other suspension can be preformed by any suitable separation process or technique, wherein the separation of solid semi-zeolitic silica and remaining liquid solvent, amorphous silica, and unreacted structure directing agent is performed. The corresponding SZS after annealing are termed as “L-SZS” and “A-SZS” respectively. In accordance with an exemplary embodiment, an on-wafer crystallization technique to convert the precursors that only display amorphous feature into crystalline semi-zeolitic silica has been developed. The crystallinity change is identified by the high resolution transmission electronic microscopy (HR-TEM) and powder X-ray diffraction (XRD). The Fourier transform infrared spectroscopy (FT-IR) and Thermogravimetric analysis (TGA) indicate that the SZS after annealing also possess structures similar to zeolites. In addition, spin-on films of precursor can undergo convenient on-wafer crystallization and thereafter possess similar k-value, stronger mechanical property, smoother and striation-free surface comparing with zeolite films.

### EXEMPLARY EMBODIMENTS

In accordance with an exemplary embodiment, an H-MEL suspension was synthesized as follows: 30 g of tetraethyl orthosilicate (TEOS, 98%, Aldrich), 27.46 g of tetrabutylammonium hydroxide (TBAOH, 40%, Sachem), and 14 g of double deionized (DDI) water were mixed at room temperature for one day. The corresponding molar composition of 1 TEOS: 0.3 TBAOH: 12 H₂O. The obtained solution was heated at 80° C. with stirring in oil-bath for 2 days and 114° C. in Teflon-lined autoclaves for 1 day subsequently. In accordance with another exemplary embodiment, an A-precursor was synthesized with the same recipe and heated at 80° C. for 13 days. However, it can be appreciated that the A-precursor can be synthesized with the same recipe and heated at approximately 50° C. to 120° C. for approximately 5 days to 30 days.

An L-precursor was prepared from the leftover after centrifugation of the as-synthesized H-MEL suspension at 20,000 rpm angular velocities for 3 h (hours) with Beckman J2-HS. Stable non-zeolitic-silica (N-ZS) (i.e., amorphous silica (AS)) was obtained by stirring of the mixture of 1 TEOS (10 g, 98%): 0.1 TBAOH (2.22 g, 40%): 3 ethanol (6.63 g): 32.58 DDI water (H₂O) (28.17 g) for 4 h (hours) at room temperature. The as-synthesized H-MEL suspension, the L-precursor and the A-precursor were diluted in pentanol and spun onto the silicon substrates on a Laurell spin coater (WS-400A-6NPP/LITE) at 3,000 rpm angular velocities at room temperature. It can be appreciated that the L-precursor and the A precursor can be spun onto the silicon substrate (or wafer) between 100 and 6000 rpm without departing from the present invention. The obtained films were baked in air for 8 hours at 80° C. and subsequently annealed at 400° C. for 2 hours to grow the precursor into MEL as well as to remove the structure directing agent. All the heating rates were 1K/min and the thermal treatments were carried out at ambient pressure. For characterization, the precursors and the H-MEL suspension were also dehydrated into powder at room temperature in vacuum, and then baked in air with the same heating program with the films. It can be appreciated that the annealing process can be carried out at approximately 150° C. to 500° C.; however, the annealing process is preferably performed at approximately (or at least) 400° C. to remove the structure directing agent from the L-precursor and/or A-precursor. In accordance with an exemplary embodiment, the A-precursor can be a mixture of A-precursors having different heat (or bake) times, e.g., 10 days and 13 days, which are combined prior to the application of the A-precursor to the wafer by a spin coating process.

It can be appreciated that in accordance with another exemplary embodiment, that the above-mentioned L-MEL synthesis is not limited to centrifugation as the only separation technique, and that any suitable separation process or technique, wherein the separation of solid semi-zeolitic silica and remaining liquid solvent, amorphous silica, and unreacted structure directing agent is performed. The synthesis solution in an alternative embodiment can include a silica source, such as tetraethylorthosilicate, ludox, or fumed silica, an organic structure directing agent, such as a quaternary ammonium compound, and a solvent, such as water or ethanol. In addition, the dilution step can be preformed any suitable solvent, such as alcohols. It can be appreciated that in accordance with another exemplary embodiment, the spun-on films can be baked from 0 to 24 hours at 50° C. to 120° C., annealed from 1 to 24 hours at 150° C. to 500° C., and the heating rate can be from approximately 1 K/min to infinity K/min.

The toluene adsorption/desorption isotherms of the films were obtained by monitoring a fixed angle ellipsometer at the wavelength 300-800 nm during the toluene adsorption and desorption. Before k measurement, the films were silylated with vapour trimethylchlorosilane. It can be appreciated that in accordance with an alternative embodiment, the films can be silylated with trimethylchlorosilane (TMCS); dimethyldichlorosilane; methyltrichlorosilane; other alkylchlorosilanes, such as (CH₃(CH₂)ₙ)ₓSiCl₄₋ₓ, where x is 1, 2, or 3; alkoxychlorosilanes; hexamethyldisilazane (HMDS); or other aminosilanes. In accordance with an exemplary embodiment, k-values were calculated from the measured capacitances. The mechanical property was measured on an Ubil nanoindentation test instrument (Hysitron, Inc., Minneapolis, MN) with a cube corner tip of 40 nm radius. The elastic moduli were calculated from measured reduced elastic moduli and the poisson's ratio was chosen from previously calculated values. Roughness investigation was carried out on an AFM (Veeco Dimension 5000) under contact mode. All the roughness measurements were taken with the same 20 nm radius probe. HR-TEM images of the films were taken by a Philips TEM (Tecnai 12) at an accelerating voltage of 120 kV. Powder crystalline phases were identified by XRD from Bruker D8 Advance Diffractometer using Cu K radiation and by FT-IR recorded on a Bruker Equinox 55. Scanning electron microscopy (SEM) images are taken with a Philips XL30-FEG operated at 10 kV and the optical microscopy images were taken with a Nikon Eclipse ME 600 microscope.

### Synthesis of L-SZS Precursor and A-SZS Precursor

In accordance with another exemplary embodiment, an A-precursor was synthesized with the mixture of 1 TEOS (tetraethyl orthosilicate): 0.2-0.5 TBAOH (tetrabutylammonium hydroxide) or 0.2-0.5 TPAOH (tetrapropylammonium hydroxide): 10 H₂O. One example is 30 g of TEOS (98 wt %), 27.46 g of TBAOH (40 wt % aqueous solution) and 14 g of double deionized (DDI) H2O. Another example is the mixture of 32 g of TEOS (98%), 30.47 g of ethanol, 32 g of DDI H₂O and 25.6 g of TPAOH (40 wt %). The mixture was heated at the temperature between 50° C. and 120° C. for at least one hour, and more preferably 5 to 30 days.

In accordance with an exemplary embodiment, to obtain the L-precursor, the synthesized pure-silica-zeolite (PSZ) MEL nanoparticle suspension can be subjected to ultra-speed centrifugation (Beckman J2-HS) at over 10,000 rpm angular velocities for at least 10 min. A PSZ MEL suspension was synthesized from the mixture of 30 g of TEOS (98 wt %), 27.46 g of TBAOH (40 wt % aqueous solution) and 14 g of DDI H₂O in a polypropylene bottle and the molar ratio is 1 TEOS: 0.3 TBAOH: 10 H2O. The solution was aged at room temperature under stirring for one day, subsequently placed into an oil bath at a temperature from approximately 40° C. to 100° C. with stirring for at least an hour, and then transferred into Teflon-lined autoclaves at a temperature between approximately 100° C. and 200° C. for at least 10 min. It can be appreciated that in accordance with another exemplary embodiment, any suitable separation process or technique, wherein the separation of solid semi-zeolitic silica and remaining liquid solvent, amorphous silica, and unreacted structure directing agent is performed can be implemented.

Conversion of Precursor into Semi-Zeolitic Silica and On-Wafer Crystallization

In accordance with another exemplary embodiment, the precursors were dehydrated under vacuum and subsequently heated at the temperature of at least 120° C. for at least an hour at ambient pressure to convert into semi-zeolitic silica (SZS).

The produced precursor can then be spun onto a substrate (i.e., “spin-on films”). The spin-on films were thermally treated at the temperature at least 120° C. for at least an hour. As the characterization results indicate that the precursor films can crystallize during annealing, this process is termed, “on-wafer crystallization”.

HR-TEM images of precursor film and SZS film respectively are shown in FIG. 2. Before annealing, no lattice is observed (FIG. 2(a)) in the obtained HR-TEM images. After annealing, as shown in FIGS. 2(b)-2(c), regular lattices are demonstrated (circled in FIG. 2(b)), and in the enlarged or zoomed-in image of FIG. 2(c). It can be appreciated that the SZS precursor can undergo on-wafer crystallization to transform into a crystalline structure.

FIG. 3 shows powder XRD patterns of L-SZS and A-SZS and the corresponding precursors. As shown in FIG. 3, the powder XRD patterns indicate the overall crystallinity increase of both L-SZS and A-SZS during annealing. The L-SZS precursor pattern changes from mostly amorphous feature before annealing into characteristic MEL structure after annealing. A-precursor only shows pure amorphous pattern, whereas A-SZS one possesses broad peaks corresponding to zeolite MEL structure.

While the XRD pattern indicates the long-range crystalline structure, short-range zeolitic structure can be identified by the FT-IR spectra. The FT-IR spectra comparison of MEL, A-SZS, A-precursor, L-SZS, L-precursor, and non-zeolitic-silica (N-ZS) are shown in FIG. 4. For comparison with SZS, pure amorphous N-ZS, which has no potential to develop into zeolite-like structure was synthesized with the mixture of 10 g of TEOS (98%), 2.22 g of TBAOH (40%, aqueous solution), 6.63 g of ethanol, and 28.17 g of DDI H₂O (double deionized water) under stirring for at least an hour at room temperature. The mixture having a corresponding molar ratio of 1 TEOS: 0.1 TBAOH: 14.56 H₂O.

All the silicate bands (1100-1020 (vs.), 800-700 (mw), and 480-440 cm⁻¹(s)) tend to be stronger after annealing due to better cross-linking and the annealed spectra demonstrate no methyl group (3000-2700 cm⁻¹) as the structure direct agents (SDA) were removed completely during annealing. According to the Flanigen-Khatami-Szymanski correlation, the band B (480-440 cm⁻¹) is supposed to appear in all the silica or quartz, including amorphous silica, whereas the band A (650-550 cm⁻¹)) has been empirically assigned to a pentasil framework (which includes a zeolite MEL framework). Therefore the ratio of band A over B offers a good probe to characterize the similarity to zeolite structure or the ordering in short-range domain. If amorphous silica is present, this ratio is expected to be smaller in proportion to the amount of disordered silica. The area ratios of the Gaussian Fitting of two bands are listed in Table 1. Both L-SZS and A-SZS have much higher ratios than the N-ZS and the ratios increase after annealing. The calculation shows that both L-SZS and A-SZS have the ordered zeolite-like structure and the ordering increases with annealing.

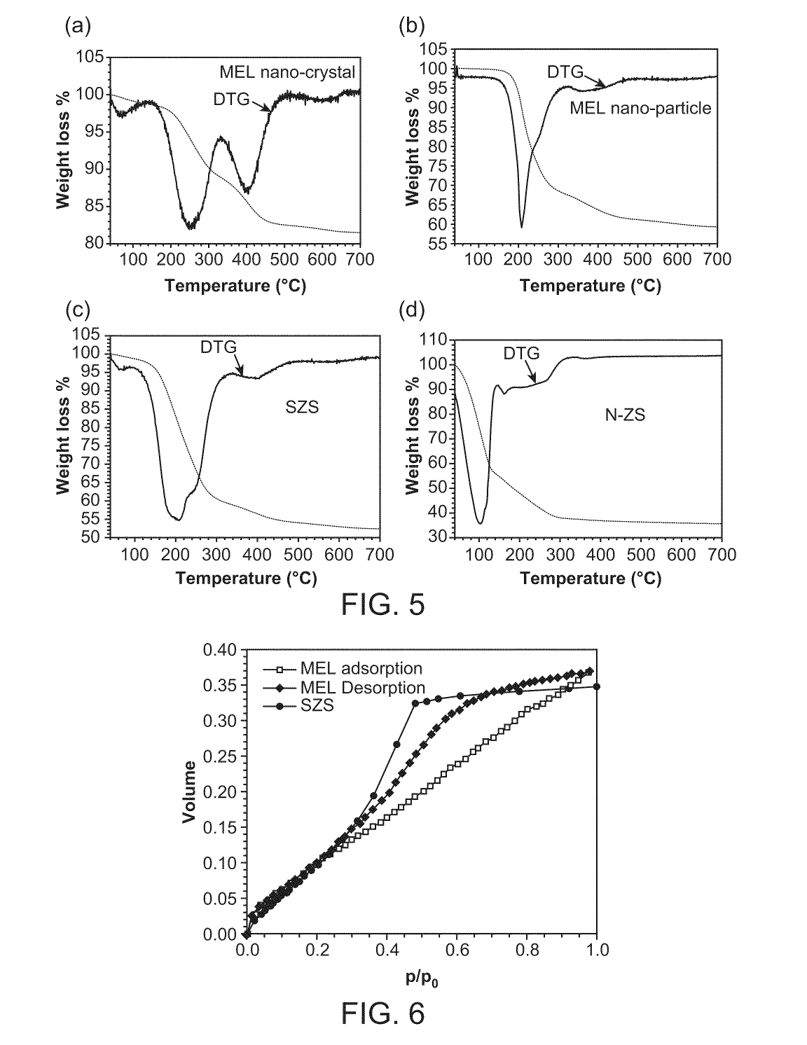

Thermogravimetric analysis (TGA) was carried out to investigate the structure of SZS. Prior to measurement, the MEL nanocrystal (crystal after centrifugation) has been washed by DDI water and ethanol many times, and therefore the physisorbed SDA attaching on the MEL external surface have been removed. All the other samples were also heated at 80° C. for 2 days to evaporate the outside solvent. The powder samples were heated from 40° C. to 700° C. at the rate of 10° C./min in air and then held at this temperature for half an hour. It can be appreciated that in accordance with another exemplary embodiment, the powder samples can be heated at a rate of 1 to 20° C./min in air, nitrogen, or oxygen, and wherein the temperature is held for approximately 0 to 4 hours. The normalized TGA and derivative curves (DTG) of MEL nanocrystal (a), MEL nanoparticle (b), SZS (c) and N-ZS (d) are shown in FIG. 5. Since there are no weight change above 700° C., for brevity, the curves after 700° C. are not shown here. The assignment and weight loss for each peak has been listed in Table 2. It can be appreciated that DTG curves of nanocrystal MEL, nanoparticle MEL and SZS powder have the similar characteristic peaks, indicating the similar structure of these three samples. While the peak positions of N-ZS are totally different from the other curves aforementioned. The SDA position in the N-ZS is different from the other silicas. The peak around 100° C. is considered as the weight loss of physisorbed water. The peak at 207° C. is attributed to the removal of physisorbed TBA+ and TBAOH species. The curve of nanocrystal MEL does not contain this step because the organic template on the external surface is washed out before measurement. The next two steps of weight loss are associated with the loss of occluded structure directing agent (SDA) in the zeolite structure. In the synthesized zeolite powder, there are two different types of nano-pores: mesopores and micropores. In accordance with an exemplary embodiment, micropore is defined as the pores smaller than 2 nm, and mesopore is defined as the pores with the size range of 2 to 50 nm. Zeolite intrinsically has the micropores around several angstroms. In the observed TEM images, the single crystal size range is between 5 to 40 nm, whereas the as-synthesized particle size analyzed by dynamic light scattering is around 80 nm. It can be appreciated that one reason for this discrepancy is that the formed primary crystals (5-40 nm) usually are not stable and tend to agglomerate into larger secondary particles (80 nm). The mesopores generate during the packing of these single-crystals. SDA will decompose differently in these two types of pores. The peaks in the differential curves at around 250° C. are related to the oxidative decomposition of TBA+and TBAOH species in the mesopores. It can be appreciated that the SZS start losing weight at slightly lower temperature than the MEL nanocrystal and nanoparticle silica, and the latter two have exactly the same peak positions. The SZS does not have the three dimensional repetition lattices in long range like nanocrystal so that the silica scaffold is packed not as regular as the MEL nanocrystal. As a result, it is easier for the occluded TBA species in SZS to decompose in the relatively loose framework. The weight loss of MEL nanoparticle at this peak can be considered the combination of 63% of nanocrystal and 37% of SZS, which is in good coincidence with the composition of MEL nanoparticle since as-synthesized nanoparticle is composed of 63% nanocrystal and 37% SZS. The broad peaks in the differential curve with the range of approximately 332° C. to 495° C. are assigned to the loss of TBA+ and TBAOH species occluded in the MEL micropores. The highest data reported regarding TGA weight loss of TBA+ in PSZ MEL nanocrystal is 2 TBA+/u.c. Here the number of TBAOH species occluded in the MEL nanocrystal agrees very well with the reported data. In the SZS, the occluded TBAOH species are less than the ones in MEL nanocrystal because even though the SZS has the zeolite-like structure, its microporosity is not as high as the MEL nanocrystal. Therefore, the SZS has zeolite-like structure but not fully developed. Again, it can be appreciated that the weight loss of MEL nanoparticle is the blending of nanocrystal and SZS according to composition ratio. The last step at around 600° C. is due to the decomposition of the silanol group binding with silicate in connectivity defects.

In accordance with an exemplary embodiment, the results of HR-TEM, XRD, FT-IR and TGA reveal that the precursor only demonstrates amorphous feature though, has the potential to crystallize during annealing and convert into semi-zeolitic-silica possessing crystalline and zeolite-like structure.

### SZS Films Applied as Ultra-Low-K Materials

The continuing shrinkage of microprocessors demands the timely development of ultra-low-dielectric-constant (k) materials to reduce parasitic capacitance, enable faster switching speeds and lower dissipation. PSZ MEL film shows low dielectric constant and strong mechanical strength, and therefore is considered as good low-k material. However, the PSZ MEL nanocrystal size is not small enough to generate smooth and striation-free spin-on film. Also etching very small features (e.g., <40 nm) on MEL film is a tough challenge. Moreover, the packing-induced mesopore sizes can be too large for the ultra-low-k films. However, it can be appreciated that SZS shows advantageous over PSZ MEL in this sense. In accordance with an exemplary embodiment, the on-wafer annealing can convert the precursor into semi-zeolitic-silica possessing crystalline structure, this ordered structure renders the spin-on SZS films ultra-low-k-value and strong mechanical property; and demonstrates the promise to further utilize the SZS as ultra-low-k dielectrics. Spin-coating from the precursors can potentially bypass the nanoparticle size concern and eliminate the struggle for simultaneously achieving high crystal yield and small particle size.

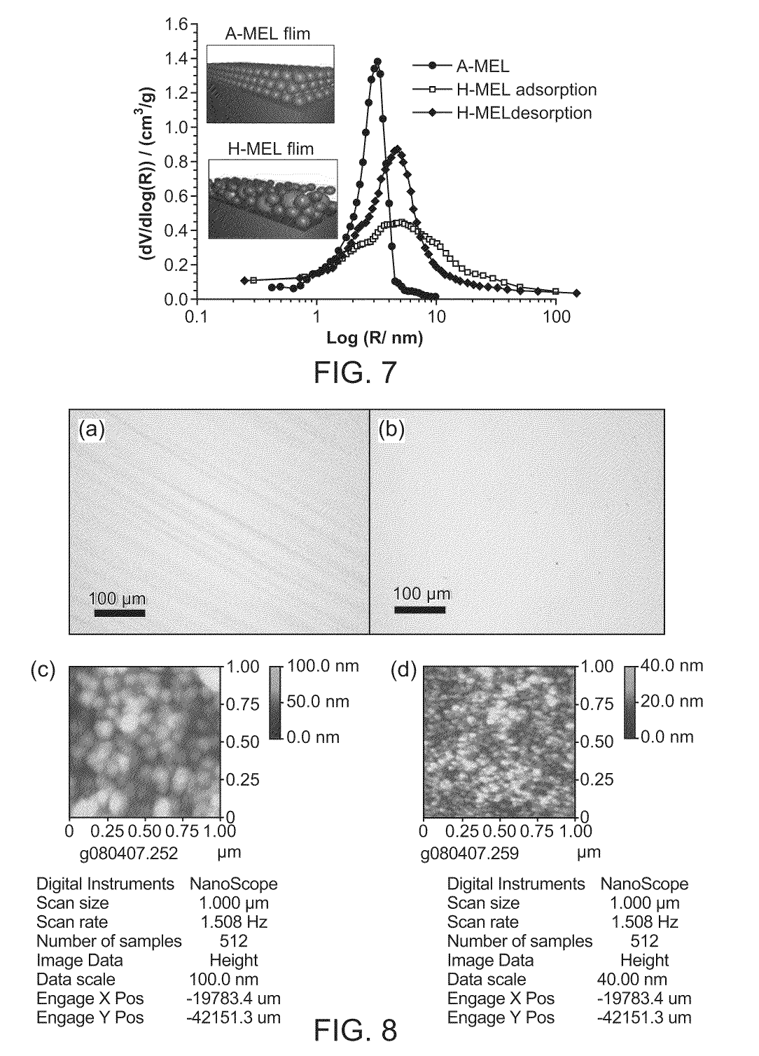

It can be appreciated that for low-k films, the pore sizes are required to be small and uniform to avoid the current leakage and breakdown. The zeolites intrinsically possess the micropores less than 1 nm. However, the packing of particles can result in large mesopores. The mesopores in both SZS film and PSZ MEL film are analyzed from the toluene adsorption/desorption isotherms (as shown in FIG. 6). For the SZS films, the toluene adsorption and desorption isotherms are the same, indicating that the mesopore size is less than 6 nm and the mesopores in the film are uniform. On the contrary, the PSZ MEL film shows different adsorption and desorption curve, and as a result the analyzed pore size distributions are also different. The pore size distribution of both SZS and PSZ MEL films are shown in FIG. 7. After on-wafer annealing, the precursor grows into nanoparticles with small and uniform sizes. In accordance with an exemplary embodiment, the packing-induced mesopore sizes are centered at 3.2 nm and very uniform (distributed within 10 nm, mostly smaller than 4 nm). These small mesopores can permit a proper sealing to avoid the electrical breakdown due to the diffusion of Cu or other conducting species. Whereas the mesopore sizes in the PSZ MEL films are centered at 4.7 nm and the distribution is spread up to 100 nm. It can be appreciated that these big pores can lead to not only electric breakdown, but also poor mechanical property of the films. It can be appreciated that by spin-on of the precursor, the packing-induced mesopores in the SZS films are much smaller and more uniform than in the PSZ MEL films.

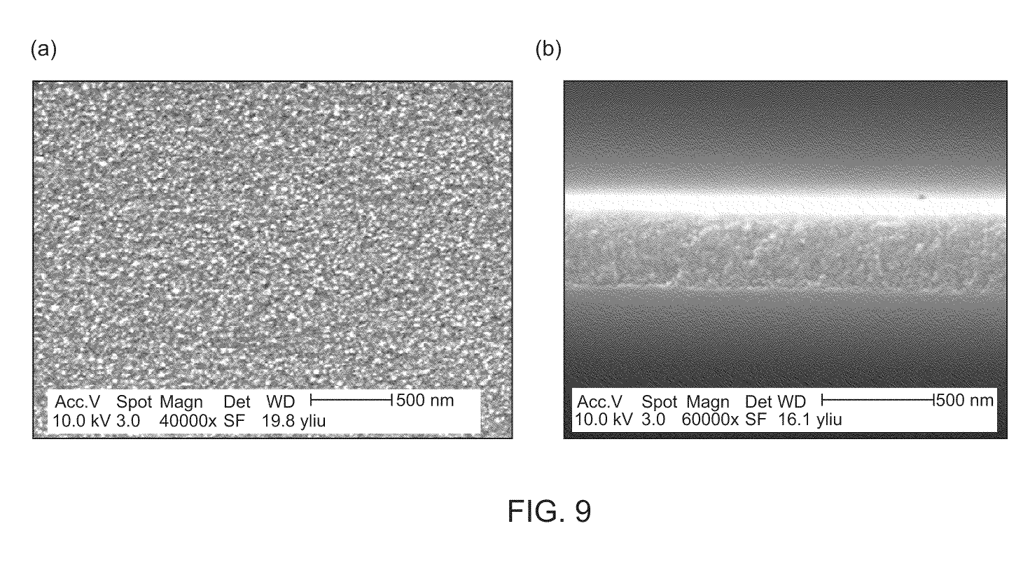

The other properties required for ultra-low-k films of the spin-on PSZ MEL and the SZS films are compared in Table 3. For example, the SZS films possess k-values as low as 1.8, similar to that of the PSZ MEL films. The low-k materials also have to be mechanically stable. It can be appreciated that during the packing process, the low-k films have to withstand significant stresses and also survive the chemical mechanical polishing (CMP) during chip processing. For example, in the semiconductor industry, the elastic modulus is used as an indicator of the capability to resist the stresses induced during packing and chip processing. An unofficial value of 6 GPa has been set as the minimum requirement; however, the higher values are always expected to perform better during the process. However, it can be appreciated that large mesopores in the PSZ MEL films can significantly lower the mechanical strength. As the SZS films have much smaller and more uniform mesopores, the elastic modulus (E) of the SZS film is more than double that of the MEL film and its hardness (H) is around 3.5 times that of the MEL film. In addition, the elastic modulus (E) of the SZS films is the highest elastic modulus reported for the ultra-low-k films. The morphology shown by both optical microscopy and atomic force microscopy (AFM) demonstrates that SZS film is smoother than PSZ MEL film (FIG. 8). The defect-free morphology is also shown in scanning electron microscopy (SEM) images (FIG. 9). The optical microscopy images show that the PSZ MEL film is striated. It can be appreciated that the non-uniform striation causes the height variation in micro scale, which in turn may lead to weak adhesion between the low-k film and the Cu wire during integration, and may affect the subsequent manufacture as well. In contrast by spin-on of the precursor, the striation-free SZS film can combat these problems. The surface roughness (R.) value of the SZS films listed in Table 3 is only about 25% of that of the MEL films, further indicating the smoothness and uniformity of the SZS films. The SZS films possess similar k-values to the PSZ MEL films, while the other properties are far better than PSZ MEL films indicating SZS film to be a much more suitable candidate as ultra-low-k dielectrics.

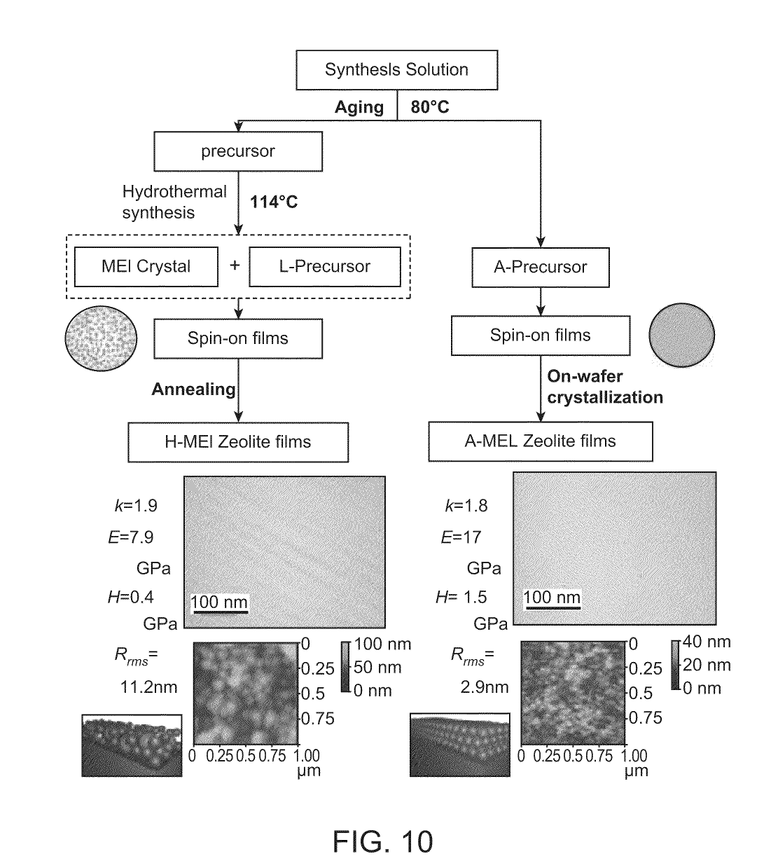

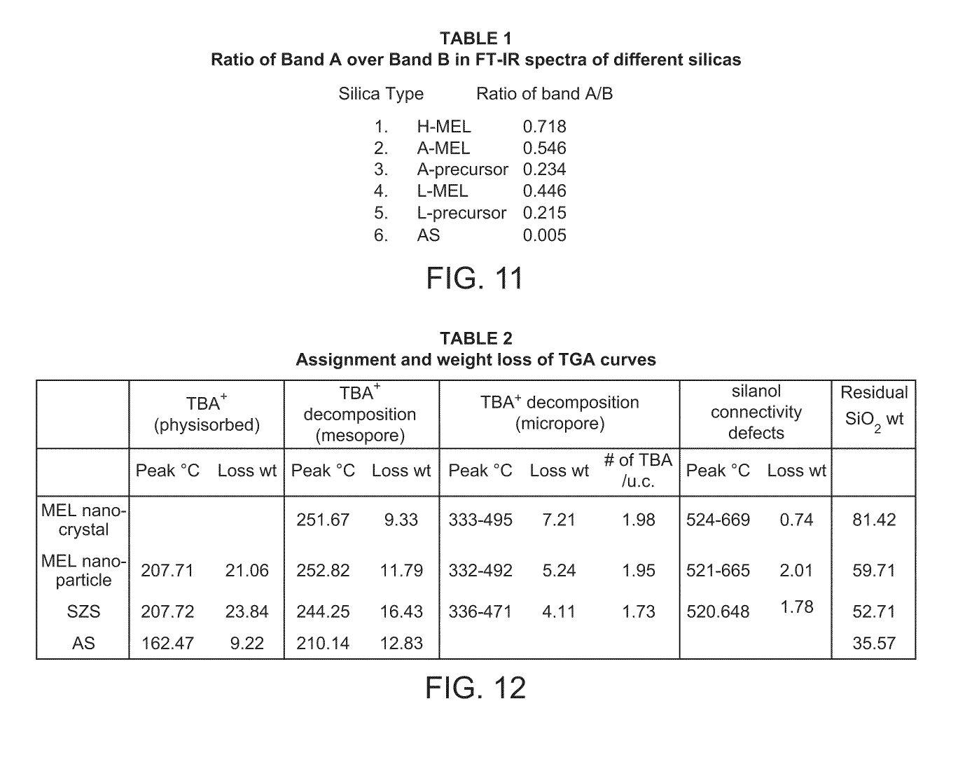

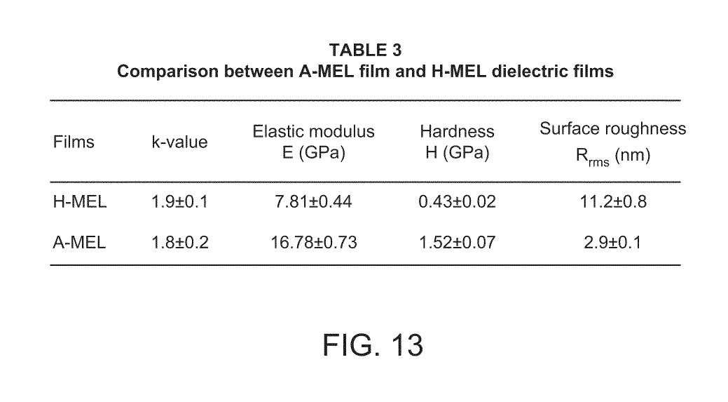

FIG. 10 is a diagram of an on-wafer crystallization process in accordance with an exemplary embodiment. As shown in FIG. 10, the on-wafer crystallization method and/or process of spin-coating a silicon wafer with a low-k dielectric zeolite material includes the steps of forming a synthesis solution, which is heated (i.e., aged) at a temperature of 50° C. to 120° C., and more preferably at 80° C. for 1 to 5 days for nucleation without crystal growth. In accordance with one exemplary embodiment, the temperature of the precursor is then increased (preferably abruptly) to 80° C. to 150° C. and more preferably approximately 114° C. (i.e., hydrothermal synthesis) and kept for several hours to 1 to 5 days to grow the nuclei into small crystals. A centrifugation or other suitable separation process (or method) of the hydrothermal synthesized precursor is performed, which produces MEL crystals and the as-synthesized PSZ MEL suspension (or L-Precursor). The MEL crystals and the as-synthesized PSZ MEL suspension (or L-Precursor) is then spun-on to a substrate (or wafer) and an annealing process is performed, which produces an H-MEL Zeolite film. In accordance with an exemplary embodiment, the annealing process is performed at between 150° C. and 500° C., and more preferably at approximately 400° C.

As shown in FIG. 10, in accordance with an alternative embodiment, an aged ambient pressure precursor (or A-precursor) can be produced by synthesizing the synthesis solution at a temperature of approximately 50° C. to 120° C. and more preferably at approximately 80° C. The A-precursor is then spun-on to a substrate (or wafer) and an annealing process performed at between 150° C. and 500° C., and more preferably at approximately 400° C.

It can be appreciated that as shown, the SZS films outperform PSZ MEL as ultra-low-k dielectrics in term of k-value, morphology, mechanical property, and mesopore size. It can be appreciated that the spin-on of a SZS (semi-zeolitic silica) precursor can bypass all the particle size issues and avoid the trade-of of particle size and crystal yield that has been pursued in the development of pure silica zeolite for years. In addition, the entire A-SZS film preparation process is carried out at ambient pressure, different from the two-stage or in-situ synthesis techniques which involve the autogenous pressure in a sealed reactor, and thus is more acceptable to industry. This on-wafer crystallization transformation at ambient pressure provides a new route to prepare zeolite-like films with tunable crystallinity and properties, and potentially applicable in different fields.

It can be appreciated that in accordance with an exemplary embodiment, the reservoir of zeolite nuclei can be prepared at relatively low temperature (i.e., 50° C. to 120° C.) and the spin-coated nuclei film can easily transform into crystalline structure on the silicon wafer. Based on this finding, it can be appreciated that in accordance with an exemplary embodiment, the on-wafer crystallization method converts a precursor film into a zeolite film, which can be used for ultra-low-k applications. In accordance with an exemplary embodiment, the A-MEL films outperform previously developed H-MEL films in term of all the requirements for ultra-low-k dielectrics, such as the k-value, mechanical strength, surface roughness, satiation, and the pore size distribution. Different from the two methods, in-situ crystallization and spin-on techniques, which involve nanoparticle suspension synthesis at the autogenous pressure in a sealed reactor, the A-MEL films can be generated completely at ambient pressure and thus is friendlier toward manufacturing. Moreover, the aging and on-wafer crystallization procedure allow for fine tuning the film properties for different applications.

In one aspect, this invention thus comprises providing a semiconductor device that comprises a semiconductor substrate, one or more metal layers or structures, and one or more dielectric films, wherein at least one dielectric film comprises an on-wafer crystallization procedure as described above.

By “semiconductor substrate” is meant substrates known to be useful in semiconductor devices, i.e. intended for use in the manufacture of semiconductor components, including, for instance, focal plane arrays, opto-electronic devices, photovoltaic cells, optical devices, transistor-like devices, 3-D devices, silicon-on-insulator devices, super lattice devices and the like. Semiconductor substrates include integrated circuits preferably in the wafer stage having one or more layers of wiring, as well as integrated circuits before the application of any metal wiring. Indeed, a semiconductor substrate can be as simple a device as the basic wafer used to prepare semiconductor devices. The most common such substrates used at this time are silicon and gallium arsenide.

It can be appreciated that the films of this invention may be applied to a plain wafer prior to the application of any metallization. Alternatively, they may be applied over a metal layer, or an oxide or nitride layer or the like as an interlevel dielectric, or as a top passivation coating to complete the formation of an integrated circuit.

It will be understood that the foregoing description is of the preferred embodiments, and is, therefore, merely representative of the article and methods of manufacturing the same. It can be appreciated that many variations and modifications of the different embodiments in light of the above teachings will be readily apparent to those skilled in the art. Accordingly, the exemplary embodiments, as well as alternative embodiments, may be made without departing from the spirit and scope of the articles and methods as set forth in the attached claims.

What is claimed is:

1. An on-wafer crystallization method of spin-coating a silicon wafer with a low-k dielectric zeolite material comprising:
forming a synthesis solution;
generating a nucleated precursor solution;
spin-coating the nucleated precursor solution onto a substrate as a precursor film; and
annealing the precursor film into a zeolite film.

2. The method of claim 1, wherein the synthesis solution comprises TEOS (tetraethyl orthosilicate), TBAOH (tetrabutylammonium hydroxide), and/or TPAOH (tetrapropylammonium hydroxide), and water (double deionized).

3. The method of claim 1, wherein the synthesis solution comprises a silica source, such as tetraethylorthosilicate, ludox, or fumed silica, an organic structure directing agent, such as a quaternary ammonium compound, and a solvent, such as water or ethanol.

4. The method of claim 1, wherein the nucleated precursor solution is generated by heating the synthesis solution at a temperature of approximately 50° C. to 120° C.

5. The method of claim 1, wherein the nucleated precursor solution is generated by heating the synthesis solution in a two-stage process, wherein a first stage is preformed at approximately 50° C. to 120° C., and second stage is preformed at approximately 80° C. to 150° C.

6. The method of claim 1, further comprising separating the nucleated precursor solution from crystal particles.

7. The method of claim 6, wherein the nucleated precursor solution is separated from the crystal particles by centrifugation.

8. The method of claim 1, further comprising baking the spin-coated precursor film onto the substrates prior to annealing in air, nitrogen, or oxygen at a temperature of approximately 50° C. to 120° C.

9. The method of claim 1, wherein the step of annealing the spin-coated precursor film into a zeolite film is performed at a temperature of approximately 150° C. to 500° C.

10. The method of claim 1, wherein baking and annealing the precursor film into a zeolite film is performed at ambient pressure.

11. An on-wafer crystallization method of spin-coating a silicon wafer with a low-k dielectric zeolite material comprising:
generating a nucleated precursor solution from a synthesis solution;
spin-coating the nucleated precursor solution onto a substrate as a precursor film; and
annealing the precursor film into a zeolite film.

12. The method of claim 11, wherein the nucleated precursor solution is generated by heating the synthesis solution at a temperature of approximately 50° C. to 120° C.

13. The method of claim 11, wherein the step of annealing the precursor film into a zeolite film is performed at a temperature of approximately 150° C. to 500° C.

14. The method of claim 11, further comprising baking the precursor film on the substrates prior to annealing in air at a temperature of approximately 50° C. to 120° C.

15. The method of claim 11, wherein the synthesis solution comprises TEOS (tetraethyl orthosilicate), TBAOH (tetrabutylammonium hydroxide), and/or TPAOH (tetrapropylammonium hydroxide), and water (double deionized).

16. The method of claim 11, wherein the substrate is a silicon wafer.

17. The method of claim 11, wherein annealing the precursor film into a zeolite film is performed at ambient pressure.

18. The method of claim 11, wherein nucleated precursor solution for the spin-on process is obtained from a mixture of nucleated precursor solutions generated by heating the synthesis solution to a temperature of approximately 50° C. to 120° C., and wherein the nucleated precursor solution for the spin-on process is a mixture of nucleated solutions having different heating times.

19. A method of forming a nucleated precursor solution for on-wafer crystallization for pure-silica-zeolite films comprising:
preparing a synthesis solution;
heating the synthesis solution at a temperature of approximately 50° C. to 120° C. for approximately 1 to 5 days and then to a temperature of approximately 80° C. to 150° C. for approximately 1 to 5 days to form a suspension of nuclei and crystals; and
separating the nuclei from the crystals by centrifugation.

20. The method of claim 19, wherein the synthesis solution comprises TEOS (tetraethyl orthosilicate), TBAOH (tetrabutylammonium hydroxide), and/or TPAOH (tetrapropylammonium hydroxide), and water (double deionized).

21. The method of claim 19, wherein the synthesis solution comprises a silica source, such as tetraethylorthosilicate, ludox, or fumed silica, an organic structure directing agent, such as a quaternary ammonium compound, and a solvent, such as water or ethanol.
